(19) United States
(12) Patent Application Publication
(10) Pub. No.: US 2024/0063201 A1
(43) Pub. Date: Feb. 22, 2024

(54) NON-CONDUCTIVE FILM FOR BONDING A FLIP CHIP DIE TO A SUBSTRATE

(71) Applicant: Micron Technology, Inc., Boise, ID (US)

(72) Inventors: See Hiong LEOW, Singapore (SG); Hong Wan NG, Singapore (SG); Seng Kim YE, Singapore (SG); Kelvin Aik Boo TAN, Singapore (SG); Ling PAN, Singapore (SG)

(21) Appl. No.: 17/820,395

(22) Filed: Aug. 17, 2022

(51) Int. Cl. H01L 25/18; H01L 23/00

(52) U.S. Cl. CPC H01L 25/18; H01L 24/16; H01L 24/32; H01L 24/73; H01L 24/92; H01L 2224/16225; H01L 2224/32225; H01L 2224/73204; H01L 2224/92125; H01L 2224/13147; H01L 2924/014; H01L 24/13; H01L 2224/29199; H01L 24/29; H01L 2224/29299

(57) ABSTRACT

Implementations described herein relate to various semiconductor device assemblies. In some implementations, a semiconductor device assembly may include a substrate, a flip chip die electrically coupled to the substrate via a plurality of electrical connections, and a non-conductive film disposed between the flip chip die and the substrate. The non-conductive film may surround the plurality of electrical connections and mechanically couple the flip chip die to the substrate.

### TECHNICAL FIELD

The present disclosure generally relates to semiconductor devices and methods of forming semiconductor devices. For example, the present disclosure relates to a non-conductive film for bonding a flip chip die to a substrate.

### BACKGROUND

A semiconductor package includes a casing that contains one or more semiconductor devices, such as integrated circuits. Semiconductor device components may be fabricated on semiconductor wafers before being diced into die and then packaged. A semiconductor package protects internal components from damage and includes means for connecting internal components to external components (e.g., a circuit board), such as via balls, pins, or leads. A semiconductor package may include one or more semiconductor die electrically coupled to a substrate, such as a printed circuit board (PCB). A semiconductor die may be electrically coupled to a substrate (e.g., PCB) using wire bonding, bump bonding, or a similar bonding technique. A semiconductor package is sometimes referred to as a semiconductor device assembly.

### BRIEF DESCRIPTION OF THE DRAWINGS

FIG. 1 is a diagram illustrating an example system associated with semiconductor packages implementing a non-conductive film for bonding a flip chip die to a substrate.

FIGS. 2A-2B are diagrammatic views of an example semiconductor package described herein. FIG. 2A is a top view of example apparatus that includes a flip chip die attached to a substrate using an underfill process, and an example apparatus that includes a flip chip die attached to a substrate using a non-conductive film. FIG. 2B is a side cross-sectional view along the line 2B-2B of FIG. 2A.

FIGS. 3A-3B are diagrammatic views example semiconductor packages described herein. FIG. 3A is a top view of example apparatus that includes a flip chip die attached to a substrate using an underfill process, and an example apparatus that includes a flip chip die attached to a substrate using a non-conductive film. FIG. 3B is a side cross-sectional view along the line 3B-3B of FIG. 3A.

FIG. 4 is a diagram of example equipment used to manufacture various semiconductor die described herein.

FIG. 5 is a diagram of an example process associated with laminating a non-conductive film on a flip chip die.

FIG. 6A is a diagram of an example process flow associated with attaching a flip chip die to a substrate using an underfill process, and FIG. 6B is an example process flow associated with attaching a flip chip die to a substrate using a non-conductive film.

FIG. 7 is a flowchart of an example method of forming an integrated assembly or memory device having a non-conductive film for bonding a flip chip die to a substrate.

FIG. 8 is a flowchart of an example method of forming a flip chip die having a non-conductive film for bonding the flip chip die to a substrate.

FIG. 9 is a flowchart of an example method of forming an integrated assembly or memory device having a non-conductive film for bonding a flip chip die to a substrate.

### DETAILED DESCRIPTION

Memory devices and similar components may include one or more semiconductor packages, also referred to as semiconductor device assemblies. At a high level, a semiconductor package may include one or more semiconductor devices, such as integrated circuits or similar components. A semiconductor device may include one or more semiconductor die electrically coupled to a substrate, such as a printed circuit board (PCB) or a similar substrate. A semiconductor die may be electrically coupled to a substrate (e.g., PCB) using wire bonding, bump bonding (sometimes referred to as direct chip attachment (DCA) bonding), or a similar bonding technique.

In some cases, a semiconductor die may be attached to a substrate using a flip chip attachment, sometimes referred to as a flip chip bond. In a flip chip attachment, a semiconductor die or similar component (sometimes referred to as a flip chip die) may be formed with a plurality of conductive external contacts, typically in the form of solder balls or bumps, arranged in a grid pattern on an active surface of the flip chip die. During a die attachment process, the flip chip die is flipped over and placed on a substrate (e.g., a PCB) with the solder balls or bumps facing down. The solder balls or bumps of the flip chip die may be aligned with terminals on the substrate, and connected by reflowing the solder balls or bumps. A dielectric (e.g., epoxy) underfill is then interjected between the flip chip die and the surface of the substance to embed the solder balls and to mechanically couple the flip chip die to the substrate. In some cases, the epoxy underfill may control stress that may otherwise be placed on the electrical connections due to thermal expansion or the like.

While an epoxy underfill may advantageously serve to couple a flip chip die to a substrate and to control stresses on the electrical connection, using an epoxy underfill may result in several disadvantages. First, a process associated with applying and curing the underfill may be time consuming. For example, following an attachment of a flip chip die to a substrate via a mass reflow process, the area to be underfilled may undergo several cleaning, underfill preparation, underfill application, and underfill curing steps. These steps may include a flux cleaning process, a pre-underfill baking process, an underfill application process, and/or an underfill cure process. Moreover, flip chip die may be associated with a keep out zone (KOZ), which is a portion of the substrate surrounding the flip chip die in which no other components are mounted, in order to accommodate for capillary underfill bleedout. Bleedout refers to the underfill extending on a substrate surface beyond a periphery of the flip chip die, which, if excessive, may contact and interfere with neighboring components. Thus, in some cases a flip chip die is associated with the KOZ to accommodate for such bleedout. This may reduce the usable area on a substrate surface for attaching other components as well as result in relatively large semiconductor packages. Additionally, any bleedout that extends beyond the KOZ may contaminate nearby electrical connections, such as wirebond fingers, and/or interfere with mounting of nearby components, such as memory chips or other semiconductor die, resulting error-prone semiconductor device assemblies.

Some implementations described herein enable the use of a non-conductive film for attaching a flip chip die to a substrate. The non-conductive film may be laminated on a surface of the flip chip die that includes solder balls, bumps, or other electrical contacts, and the non-conductive film may cured to surround the electrical contacts and expose the bumps for bonding to a substrate. When the flip chip die is attached to a substrate, the non-conductive film may be heated and cured during a mass reflow process or the like, thereby mechanically coupling the flip chip die to the substrate and/or protecting the electrical connections of the flip chip die without the use of an epoxy underfill. As a result, a KOZ associated with the flip chip die may be reduced or eliminated, resulting in more usable area on a substrate surface for attaching other semiconductor components, and/or reducing spacing between adjacent semiconductor components, thereby resulting in smaller semiconductor packages. Moreover, contamination of and/or interference with nearby semiconductor components previously caused by excessive underfill bleedout may be eliminated, resulting in more reliable semiconductor packages and less reworking of faulty devices. Additionally, eliminating the underfill process may reduce a manufacturing cycle time, because certain processes associated with underfill application and curing, such as a flux cleaning process, a pre-underfill baking process, an underfill application process, and/or an underfill cure process, may be eliminated. These and other benefits may be better understood with reference to the drawings.

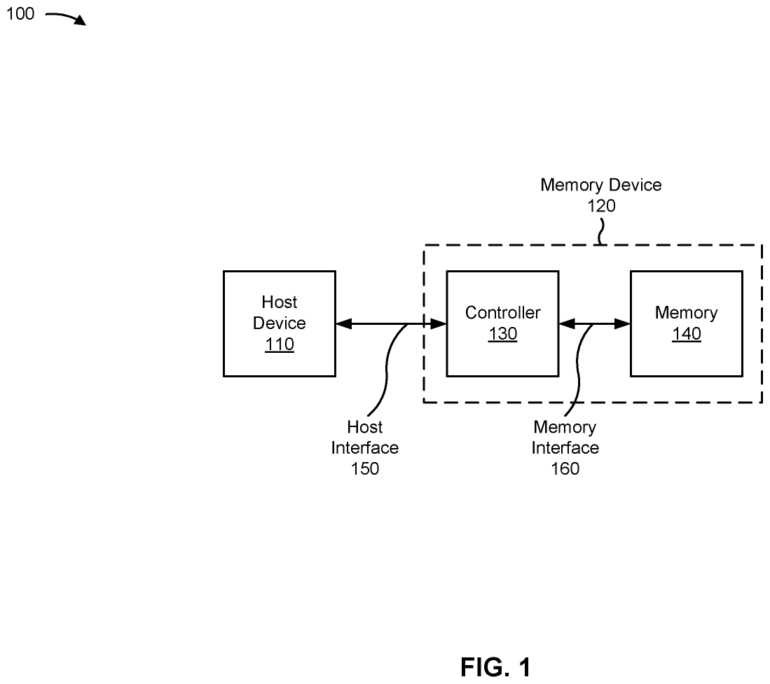

FIG. 1 is a diagram illustrating an example system 100 associated with semiconductor packages implementing a non-conductive film for bonding a flip chip die to a substrate. The system 100 may include one or more devices, apparatuses, and/or components for performing operations described herein. For example, the system 100 may include a host device 110 and a memory device 120. The memory device 120 may include a controller 130 and memory 140. The host device 110 may communicate with the memory device 120 (e.g., the controller 130 of the memory device 120) via a host interface 150. The controller 130 and the memory 140 may communicate via a memory interface 160.

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host device 110 may include one or more processors configured to execute instructions and store data in the memory 140. For example, the host device 110 may include a central processing unit (CPU), a graphics processing unit (GPU), a field-programmable gate array (FPGA), an application-specific integrated circuit (ASIC), and/or another type of processing component.

The memory device 120 may be any electronic device configured to store data in memory. In some implementations, the memory device 120 may be an electronic device configured to store data persistently in non-volatile memory. For example, the memory device 120 may be a hard drive, a solid-state drive (SSD), a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, an embedded multimedia card (eMNIC) device, and/or a managed NAND (mNAND) device. More particularly, in some implementations, the memory device 120 may be an mNAND multi-chip package (MCP) device, an mNAND universal flash storage (UFS) device, or a similar memory device. In this case, the memory 140 may include non-volatile memory configured to maintain stored data after the memory device 120 is powered off. For example, the memory 140 may include NAND memory or NOR memory. In some implementations, the memory 140 may include volatile memory that requires power to maintain stored data and that loses stored data after the memory device 120 is powered off, such as one or more latches and/or random-access memory (RAM), such as dynamic RAM (DRAM) and/or static RAM (SRAM). For example, the volatile memory may cache data read from or to be written to non-volatile memory, and/or may cache instructions to be executed by the controller 130.

The controller 130 may be any device configured to communicate with the host device (e.g., via the host interface 150) and the memory 140 (e.g., via the memory interface 160). Additionally, or alternatively, the controller 130 may be configured to control operations of the memory device 120 and/or the memory 140. For example, the controller 130 may include a memory controller, a system controller, an ASIC, an FPGA, a processor, a microcontroller, and/or one or more processing components. In some implementations, the controller 130 may be a high-level controller, which may communicate directly with the host device 110 and may instruct one or more low-level controllers regarding memory operations to be performed in connection with the memory 140. In some implementations, the controller 130 may be a low-level controller, which may receive instructions regarding memory operations from a high-level controller that interfaces directly with the host device 110. As an example, a high-level controller may be an SSD controller, and a low-level controller may be a non-volatile memory controller (e.g., a NAND controller) or a volatile memory controller (e.g., a DRAM controller). In some implementations, a set of operations described herein as being performed by the controller 130 may be performed by a single controller (e.g., the entire set of operations may be performed by a single high-level controller or a single low-level controller). Alternatively, a set of operations described herein as being performed by the controller 130 may be performed by more than one controller (e.g., a first subset of the operations may be performed by a high-level controller and a second subset of the operations may be performed by a low-level controller). In some implementations, the controller 130 may be associated with a flip chip bonding process, and thus may be referred to as a flip chip controller.

The host interface 150 enables communication between the host device 110 and the memory device 120. The host interface 150 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a UFS interface, and/or an embedded multimedia card (eMMC) interface.

The memory interface 160 enables communication between the memory device 120 and the memory 140. The memory interface 160 may include a non-volatile memory interface (e.g., for communicating with non-volatile memory), such as a NAND interface or a NOR interface. Additionally, or alternatively, the memory interface 160 may include a volatile memory interface (e.g., for communicating with volatile memory), such as a double data rate (DDR) interface.

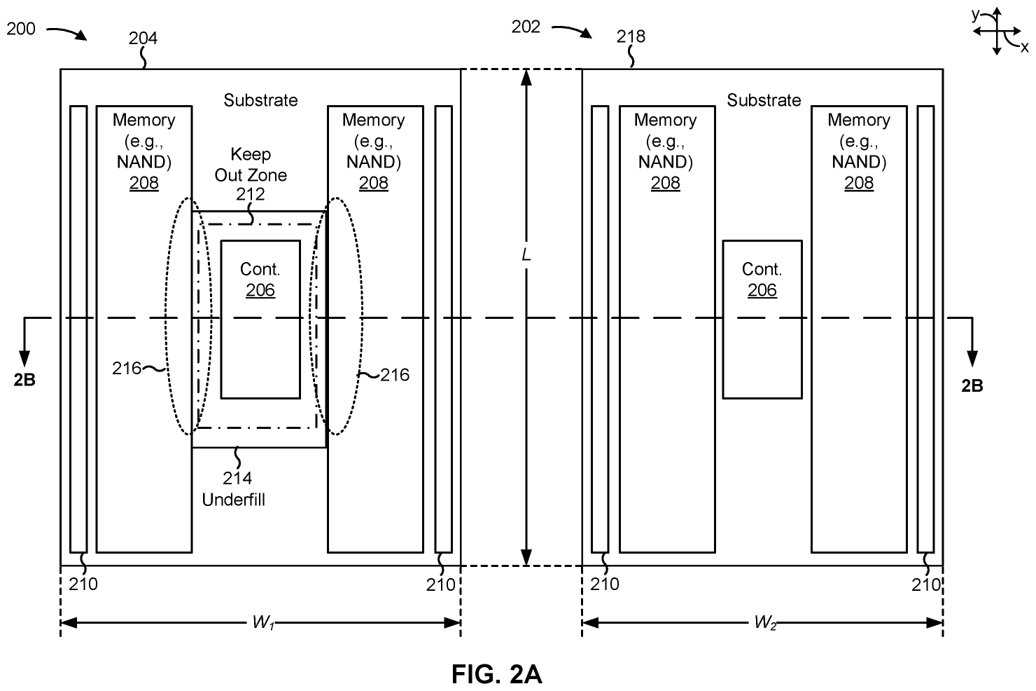

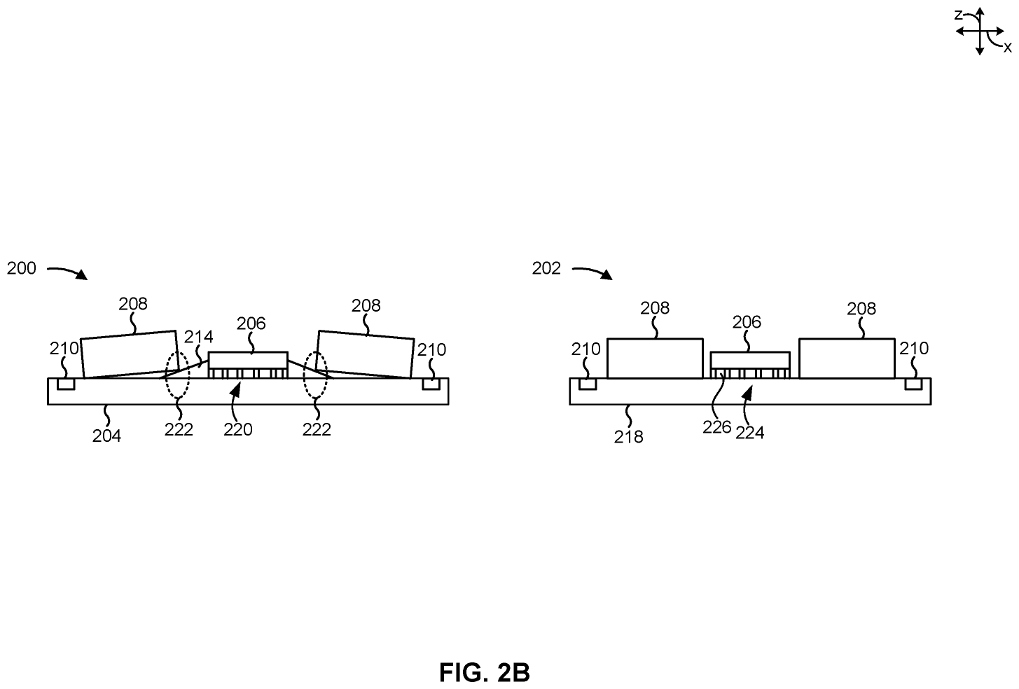

In some implementations, one or more of the host device 110 or the memory device 120 may be associated with a semiconductor package implementing a non-conductive film for bonding a semiconductor die (e.g., a flip chip die) to a substrate. For example, in some implementations, the memory device 120 may be a semiconductor conductor package including a substrate with the controller 130 and/or the memory 140 bonded thereto. In some implementations, the controller 130 and/or the memory 140 may be a flip chip die that is electrically coupled to the substrate via a plurality of bump bonds and/or that is mechanically coupled to the substrate via a non-conductive film. Aspects of electrically coupling a flip chip die to a substrate via a plurality of bump bonds and/or mechanically coupling a flip chip die to a substrate via a non-conductive film are described in more detail in connection with FIGS. 2A-9.

As indicated above, FIG. 1 is provided as an example. Other examples may differ from what is described with regard to FIG. 1.

FIGS. 2A-2B are diagrammatic views of an example semiconductor package described herein. FIG. 2A is a top view of example apparatus 200 that includes a flip chip die attached to a substrate using an underfill process, and an example apparatus 202 that includes a flip chip die attached to a substrate using a non-conductive film. FIG. 2B is a side cross-sectional view along the line 2B-2B of FIG. 2A. The apparatus 200 and/or the apparatus 202 may include any type of device or system that includes one or more integrated circuits. For example, the apparatus 200 and/or the apparatus 202 may include a memory device, a flash memory device, a NAND memory device, a NOR memory device, a RAM device, a read-only memory (ROM) device, a DRAM device, a holographic RAM (HRAM) device, an SRAM device, an SSD, a microchip, and/or a system on a chip (SoC). In some implementations, the apparatus 200 and/or the apparatus 202 may be an mNAND UFS memory device.

In some implementations, the apparatus 200 may include a substrate 204, a controller 206 coupled to the substrate 204, one or more memory die 208 (e.g., memory 140, which, in some implementations, may be a NAND die or a NAND stack) coupled to the substrate 204, and one or more bond fingers 210. In the example apparatus 200, the controller 206 may be a flip chip controller coupled to the substrate 204 using an underfill process. Additionally, or alternatively, the controller 206 may include any type of circuit, such as an analog circuit, a digital circuit, a radiofrequency (RF) circuit, a power supply, an input-output (I/O) chip, an ASIC, an FPGA, and/or a memory device (e.g., a NAND memory device, a NOR memory device, a RAM device, or a ROM device). The memory die 208 may be a component of a memory device, such as a RAM device, a ROM device, a DRAM device, an SRAM device, a synchronous dynamic RAM (SDRAM) device, a ferroelectric RAM (FeRAM) device, a magnetic RAM (MRAM) device, a resistive RAM (RRAM) device, an HRAM device, a flash memory device (e.g., a NAND memory device or a NOR memory memory), and others.

In some implementations, the controller 206 may be associated with a KOZ 212, which may be an area on the substrate 204 in which other components are not mounted in order to avoid contamination from epoxy underfill. More particularly, and as is described in more detail in connection with FIG. 2B, due to a capillary action of an epoxy underfill 214 used to fill an area between the controller 206 and the substrate 204, the epoxy underfill 214 may extend (e.g., bleedout) beyond a periphery of the controller 206. Thus, the controller 206 may be associated with the KOZ 212 to reduce the probability that the epoxy underfill 214 that extends beyond the periphery of the controller 206 will interfere with and/or contaminate neighboring components of the apparatus 200, such as one or more of the memory die 208, one or more of the bond fingers 210, and/or one or more other components of the apparatus 200. In some implementations, a boundary of the KOZ 212 may extend at least 700 micrometers (μm) from each outer edge of the controller 206. For example, the boundary of the KOZ 212 may extend between 700 μm and 1000 μm from each outer edge of the controller 206.

Despite the KOZ 212, in some implementations, the epoxy underfill 214 may nonetheless extend, or bleedout, past the KOZ 212 and contaminate or interfere with other components attached to the substrate 204 surface. For example, as indicated by the pair of dashed ellipses shown by reference number 216, in this implementation the epoxy underfill 214 may extend to the neighboring memory die 208. This may result in unevenly mounted memory die 208 or other manufacturing defects, which is described in more detail in connection with FIG. 2B.

In contrast, the controller 206 associated with the example apparatus 202 is attached to a substrate 218 without the use of an epoxy underfill. In that regard, the controller 206 in this implementation may not be associated with a KOZ (such as the KOZ 212) or else may be associated with a smaller KOZ, because there is no risk of excessive bleedout from the epoxy underfill. As a result, and as may be seen by comparing a width of the apparatus 200 (e.g., a dimension of the apparatus 200 along the x-axis direction, shown as W₁) with a width of the substrate 218 of apparatus 202 (e.g., a dimension of apparatus 202 along the x-axis direction, shown as W₂), the various components of the apparatus 200 (e.g., the controller 206 and memory die 208) may be mounted nearer to one another than the same components of the apparatus 202, reducing a package size. For example, unlike for the apparatus 200, which includes at least a 700 μm KOZ 212, the controller 206 of apparatus 202 may be disposed less than 700 μm from a closest edge of the memory die 208. In some implementations, the controller 206 of apparatus 202 may be disposed approximately 50 μm from a closest edge of the memory die 208 (e.g., a KOZ associated with the controller 206 when mounted using the non-conductive film may be approximately 50 μm). Accordingly, a semiconductor package associated with the apparatus 202 may be smaller than a semiconductor package associated with the apparatus 200. For example, in some aspects, the apparatus 200 may have a length (e.g., a dimension of the apparatus 200 along the y-axis direction, shown as L) of approximately 13 millimeters (mm) and a width (e.g., W₁ of approximately 11.5 mm, and the apparatus 202 may have a length (e.g., L) of approximately 13 mm and a width (e.g., W₂) of approximately 9.5 mm.

Additionally, or alternatively, because the controller 206 of the apparatus 202 is attached to the substrate 218 without the use of an epoxy underfill, a risk of excessive bleedout interfering with neighboring components is eliminated. More particularly, as shown in FIG. 2B, the controller 206 may include a plurality of electrical connections 220 (e.g., bump bonds) surrounded by the epoxy underfill 214. Due to a capillary bleedout effect of the epoxy underfill 214, the epoxy underfill 214 may extend outward on the substrate 204, beyond a periphery (in the x-y plane) of the controller 206, as described. More particularly, in the depicted embodiment, the epoxy underfill 214 extends into an area where the memory die 208 are to be attached to the substrate 204. In this regard, the epoxy underfill 214 may interfere with a mounting and/or proper attachment of the memory die 208 to the substrate 204. More particularly, as shown by the pair of ellipses indicated by reference number 222, the memory die 208 may sit on the epoxy underfill 214 when mounted to the substrate 204. This may result in bulging of a semiconductor package associated with the apparatus 200, faulty or missed electrical connections between the memory die 208 and the substrate 204, or other problems.

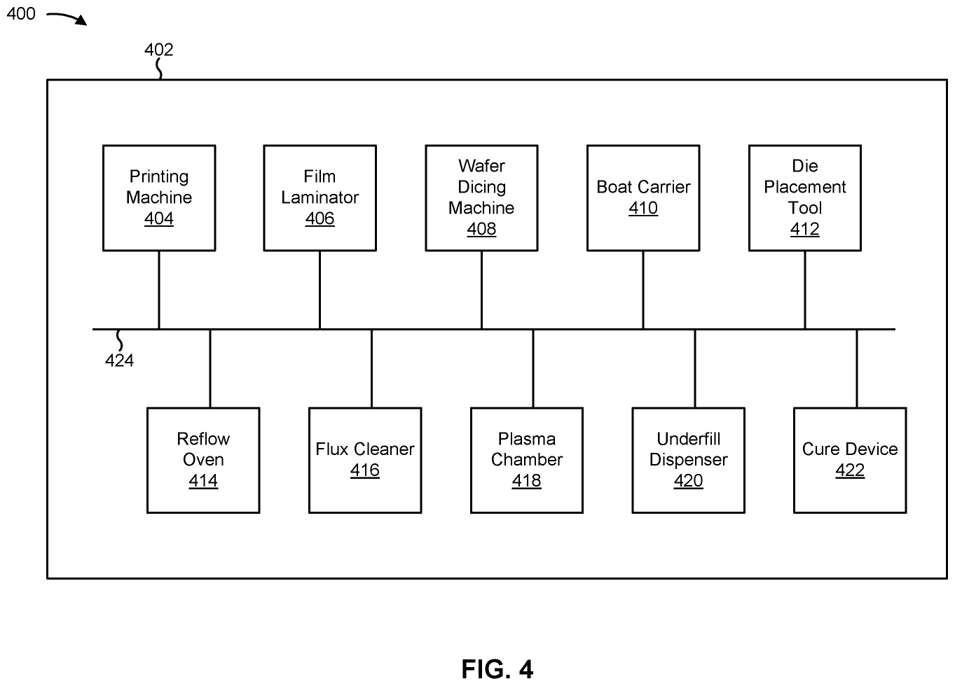

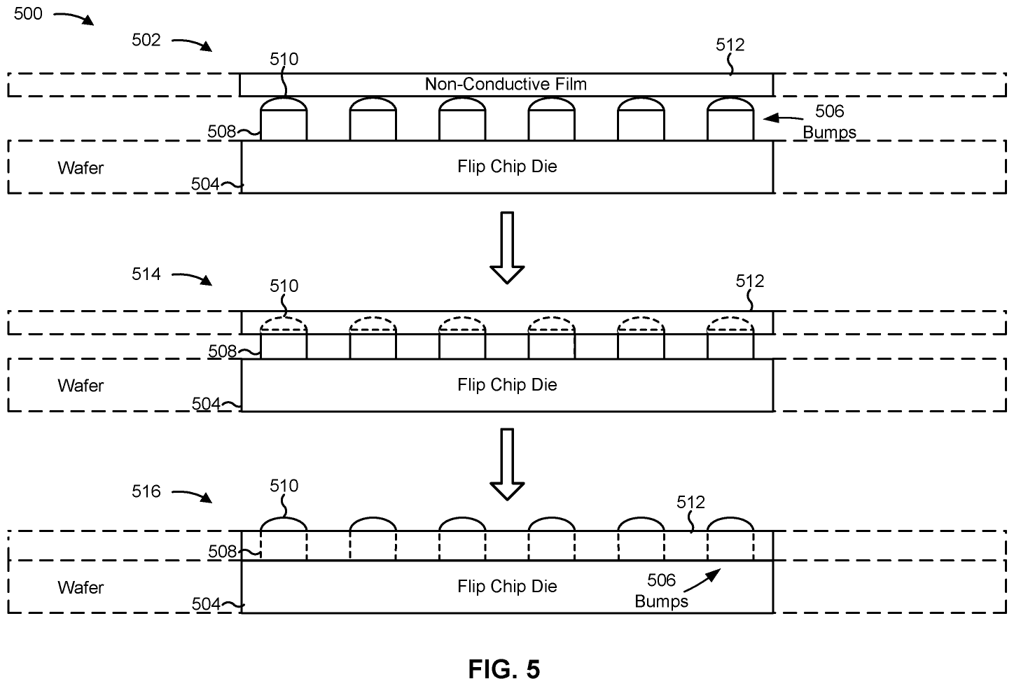

In contrast, because the controller 206 of the apparatus 202 is attached without the use of an epoxy underfill (e.g., epoxy underfill 214), there is no such interference with neighboring components on the substrate 218. More particularly, the controller 206 may include a plurality of electrical connections 224 (e.g., bump bonds) surrounded by a non-conductive film 226. The non-conductive film 226 may be disposed between the controller 206 and the substrate 218, such that the non-conductive film 226 surrounds the plurality of electrical connections 224 and mechanically couples the controller 206 to the substrate 218. In some implementations, the plurality of electrical connections 224 may include a plurality of pillar bumps capped with a plurality of solder bumps, as will be described in more detail in connection with FIG. 5. In such implementations, the non-conductive film 226 may surround the plurality of pillar bumps and expose the plurality of solder bumps for making an electrical connection to the substrate 218. In some implementations, the non-conductive film 226 may be laminated on a side of the controller 206 including the electrical connections 224 (e.g., bumps), and cured to expose the electrical connections, which is described in more detail in connection with FIGS. 4-7.

In some implementations, the non-conductive film may be laminated on a wafer used to create the controller 206, and then cured to expose the electrical connections before the wafer is diced into multiple die, including the controller 206. In such implementations, because the non-conductive film 226 is laminated on the controller 206 when the controller 206 is part of the wafer and then diced at the same time as the controller 206, an outer periphery of the non-conductive film 226 may not expend beyond a periphery (in the x-y plane) of the controller 206. Put another way, an outer periphery of the non-conductive film 226 may be fully contained within outer periphery of the controller 206. Accordingly, and as shown in FIG. 2B, the various components (e.g., the controller 206 and the memory die 208) may be mounted near to one another on the substrate 218 without risk of uneven mounting of the memory die 208 (as shown in connection with the apparatus 200). In this regard, the bulging of a semiconductor package, the faulty or missed electrical connections between the memory die 208 and the substrate 204, and the other problems caused by the use of an epoxy underfill 214 may be reduced or eliminated by use of the non-conductive film 226.

Although in the implementation described in connection with FIGS. 2A-2B, the controller 206 was described as being the flip chip component that is attached to a substrate 218 via the non-conductive film 226, implementations of the disclosure are not so limited. In some other implementations, other types of semiconductor die may be attached to the substrate 218 using a non-conductive film 226 instead of, or in addition to, the controller 206 without departing from the scope of the disclosure. For example, in some implementations, one or more of the memory die 208 may be a flip chip die that is attached to the substrate using a non-conductive film and/or without the use of an epoxy underfill. In such implementations, one or more of the benefits described in connection with the flip chip controller 206 of the apparatus 202 (e.g., a smaller semiconductor package, more space available on a substrate surface for mounting various components, an elimination of bulging of a semiconductor package, a reduction in a number of faulty or missed electrical connections between various semiconductor components and the substrate, and similar benefits) may be similarly realized by mounting the other semiconductor die to the substrate using a non-conductive film and/or without the use of an epoxy underfill.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIGS. 2A-2B are provided as an example. Other examples may differ from what is described with respect to FIG. 2A-2B.

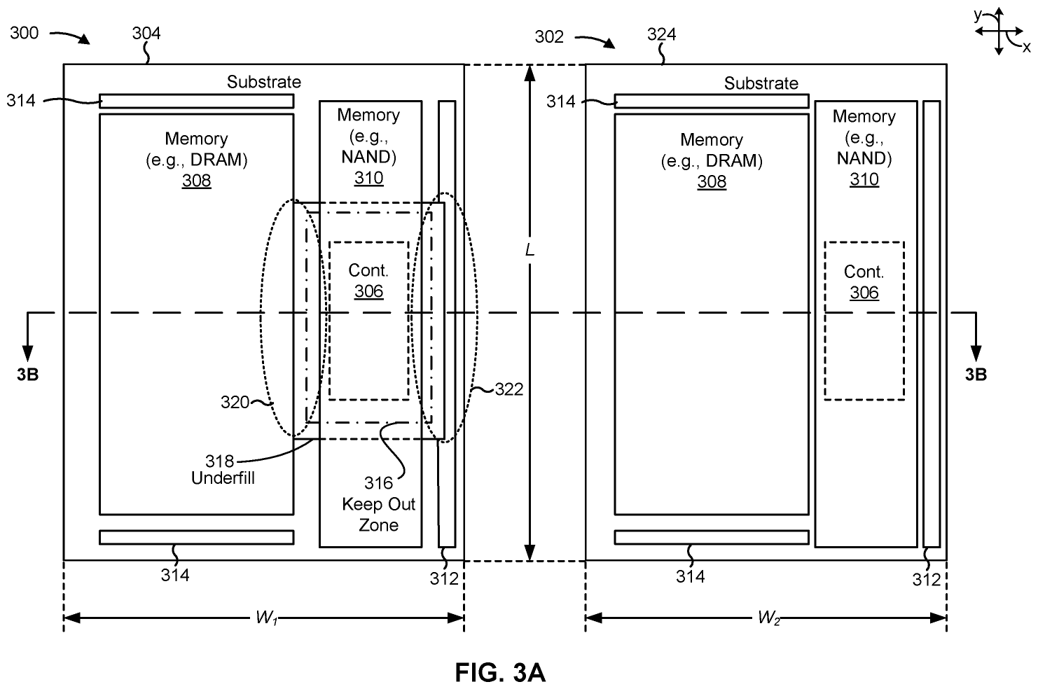

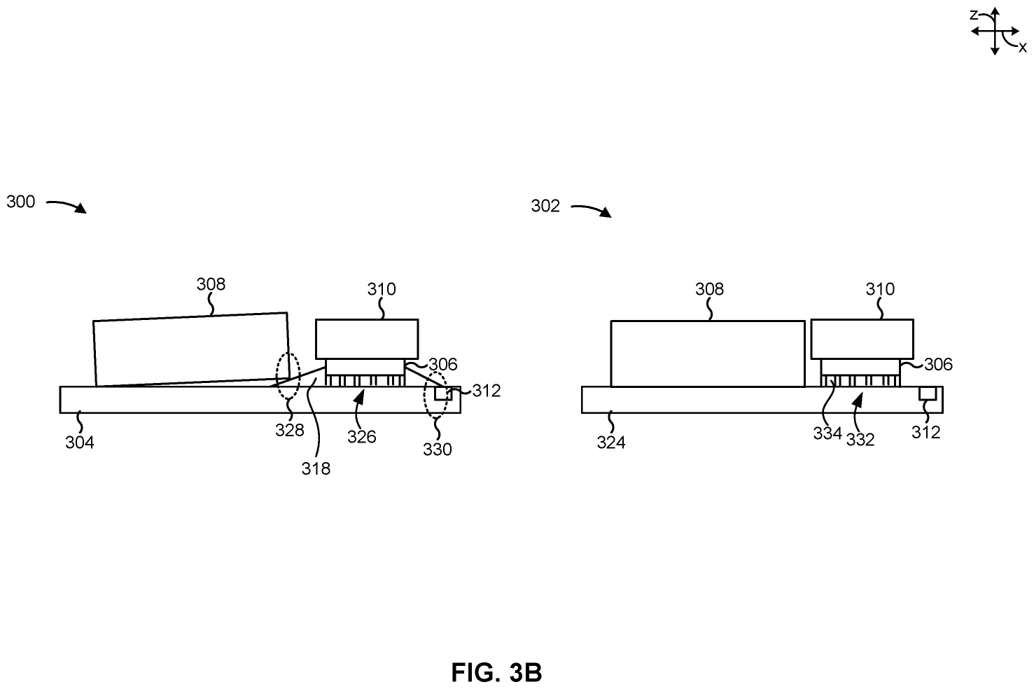

FIGS. 3A-3B are diagrammatic views example semiconductor packages described herein. FIG. 3A is a top view of example apparatus 300 that includes a flip chip die attached to a substrate using an underfill process, and an example apparatus 302 that includes a flip chip die attached to a substrate using a non-conductive film. FIG. 3B is a side cross-sectional view along the line 3B-3B of FIG. 3A. The apparatus 300 and/or the apparatus 302 may include any type of device or system that includes one or more integrated circuits. For example, the apparatus 300 and/or the apparatus 302 may include a memory device, a flash memory device, a NAND memory device, a NOR memory device, a RAM device, a ROM device, a DRAM device, an HRAM device, an SRAM device, an SSD, a microchip, and/or an SoC. In some implementations, the apparatus 300 and/or the apparatus 302 may be an mNAND MCP memory device.

In some implementations, the apparatus 300 may include a substrate 304, a controller 306 coupled to the substrate 304, one or more memory die 308, 310 (e.g., memory 140, which, in some implementations, may be one or more DRAM die and/or one or more NAND die) coupled to the substrate 304, and one or more bond fingers 312, 314. In this implementation, the controller 306 may be mounted under one of the memory die 310 (e.g., a NAND stack), which is shown in more detail in FIG. 3B. Moreover, the controller 306 may be a flip chip controller coupled to the substrate 304 using an underfill process. Additionally, or alternatively, the controller 306 may include any type of circuit, such as an analog circuit, a digital circuit, an RF circuit, a power supply, an I/O chip, an ASIC, an FPGA, and/or a memory device (e.g., a NAND memory device, a NOR memory device, a RAM device, or a ROM device). The memory die 308, 310 may be a component of a memory device, such as a RAM device, a ROM device, a DRAM device, an SRAM device, an SDRAM device, an FeRAM device, an MRAM device, an RRAM device, an HRAM device, a flash memory device (e.g., a NAND memory device or a NOR memory memory), and others. In some implementations, the memory die 308, 310 may include two different types of memory. For example, the memory die 308 may be associated with a DRAM device, and the memory die 310 may be associated with a NAND device.

In some implementations, the controller 306 may be associated with a KOZ 316, which, similar to the KOZ 212 described in connection with FIG. 2, may be an area on the substrate 304 in which other components are not mounted in order to avoid contamination from epoxy underfill 318. More particularly, and as is described in more detail in connection with FIG. 3B, due to a capillary action of an epoxy underfill 318 used to fill an area between the controller 306 and the substrate 304, the epoxy underfill 318 may extend (e.g., bleedout) beyond a periphery of the controller 306. Thus, the controller 306 may be associated with the KOZ 316 to reduce the probability that the epoxy underfill 318 will interfere with and/or contaminate neighboring components of the apparatus 300, such as one or more of the memory die 308, 310, one or more of the bond fingers 312, 314, and/or one or more other components of the apparatus 300. In some implementations, a boundary of the KOZ 316 may extend at least 1000 μm from each outer edge of the controller 306. For example, the boundary of the KOZ 316 may extend between 1000 μm and 1500 μm from each outer edge of the controller 306.

Despite the KOZ 316, the epoxy underfill 318 may nonetheless extend, or bleedout, past the KOZ 316 and contaminate or disturb other components attached to the substrate 304 surface. For example, as indicated by the pair of dashed ellipses shown by reference numbers 320 and 322, in this implementation the epoxy underfill 318 may extend to the neighboring memory die 308 and/or the neighboring bond finger 312. This may result in an unevenly mounted memory die 308, a contaminated bond finger 312, or other manufacturing defects, which is described in more detail in connection with FIG. 3B.

In contrast, the controller 306 associated with the example apparatus 302 is attached to a substrate 324 without the use of an epoxy underfill. In that regard, the controller 306 in this implementation is not associated with a KOZ (such as the KOZ 316) or else is associated with a reduced size KOZ, because there is no risk of excessive bleedout from the epoxy underfill. As a result, and as may be seen by comparing a width of the apparatus 300 (e.g., W₁) with a width of the apparatus 302 (e.g., W₂), the various components of the apparatus 302 (e.g., the controller 306 and memory die 308, 310) may be mounted nearer to one another than the same components of the apparatus 202. For example, the controller 306 may be disposed less than 1000 μm from a closest edge of the memory die 308 and/or from the bond finger 312. In some implementations, the controller 206 may be disposed approximately 50 μm from a closest edge of the memory die 308 and/or the bond finger 312 (e.g., a KOZ associated with the controller 306 when mounted using the non-conductive film may be approximately 50 μm). Accordingly, a semiconductor package associated with the apparatus 302 may be smaller than a semiconductor package associated with the apparatus 300. For example, in some aspects, the apparatus 300 may have a length (e.g., L) of 13 mm and a width (e.g., W₁) of 11.5 mm, and the apparatus 302 may have a length (e.g., L) of 13 mm and a width (e.g., W₂) of 9.5 mm.

Additionally, or alternatively, because the controller 306 of the apparatus 302 is attached to the substrate 324 without the use of an epoxy underfill, a risk of excessive bleedout interfering with neighboring components is eliminated. More particularly, as shown in FIG. 3B, the controller 306 may include a plurality of electrical connections 326 (e.g., bump bonds) surrounded by the epoxy underfill 318. Due to a capillary bleedout effect of the epoxy underfill 318, the epoxy underfill 318 may extend outward on the substrate 304, beyond a periphery (in the x-y plane) of the controller 306, as described. More particularly, in the depicted embodiment, the epoxy underfill 318 extends into an area where the memory die 308 (e.g., a DRAM die) is to be attached to the substrate 304. In this regard, the epoxy underfill 318 may interfere with a mounting and/or proper attachment of the memory die 308 to the substrate 304. More particularly, as shown by the ellipse indicated by reference number 328, the memory die 308 may sit on the epoxy underfill 318 when mounted to the substrate 304. This may result in bulging of a semiconductor package associated with the apparatus 300, faulty or missed electrical connections between the memory die 308 and the substrate 304, or other problems. Moreover, as shown by ellipse 330, the epoxy underfill 318 extends onto the bond finger 312 on the substrate 304 surface. This may interfere with electrical connections at the bond finger 312, resulting in a faulty apparatus 300 and/or semiconductor package.

In contrast, because the controller 306 of the apparatus 302 is attached without the use of an epoxy underfill, there is no such interference with neighboring components on the substrate 324. More particularly, the controller 306 may include a plurality of electrical connections 332 (e.g., bump bonds) surrounded by a non-conductive film 334. The non-conductive film 334 may be disposed between the controller 306 and the substrate 324, such that the non-conductive film 334 surrounds the plurality of electrical connections 332 and mechanically couples the controller 306 to the substrate 324. In some implementations, the plurality of electrical connections 332 may include a plurality of pillar bumps capped with a plurality of solder bumps, which is described in more detail in connection with FIG. 5. In such implementations, the non-conductive film 334 may surround the plurality of pillar bumps and expose the plurality of solder bumps for making an electrical connection to the substrate 324. In some implementations, the non-conductive film 334 may be laminated on a side of the controller 306 including the electrical connections 332 (e.g., bump bonds), and cured to expose the electrical connections 332, which is described in more detail in connection with FIGS. 4-7.

In some implementations, the non-conductive film may be laminated on a wafer used to create the controller 306, and then cured to expose the electrical connections 332 before the wafer is diced into multiple die, including the controller 306. In such implementations, because the non-conductive film 334 is laminated on the controller 306 when the controller 306 is part of the wafer and then diced at the same time as the controller 306, an outer periphery of the non-conductive film 334 may not extend beyond a periphery (in the x-y plane) of the controller 306. Put another way, an outer periphery of the non-conductive film 334 may be fully contained within outer periphery of the controller 306. Accordingly, and as shown in FIG. 3B, the various components (e.g., the controller 306, the memory die 308, and/or the bond finger 312) may be mounted near to one another on the substrate 324 without risk of uneven mounting of the memory die 308 and/or contamination of the bond finger 312 (as shown in connection with the apparatus 300). In this regard, the bulging of a semiconductor package, the faulty or missed electrical connections between the memory die 308 and the substrate 304, interference with electrical connections associated with the bond finger 312, and the other problems caused by the use of an epoxy underfill 318 may be reduced or eliminated by use of the non-conductive film 334.

Although in the implementation described in connection with FIGS. 3A-3B, the controller 306 is described as being the flip chip component that is attached to a substrate 324 via the non-conductive film 334, implementations of the disclosure are not so limited. In some other implementations, other types of semiconductor die may be attached to the substrate 324 using a non-conductive film 334 instead of, or in addition to, the controller 306 without departing from the scope of the disclosure. For example, in some implementations, one or more of the memory die 308, 310 may be a flip chip die that is attached to the substrate using a non-conductive film and/or without the use of an epoxy underfill. In such implementations, one or more of the benefits described in connection with the flip chip controller 306 of apparatus 302 (e.g., a smaller semiconductor package, more space available on a substrate surface for mounting various components, an elimination of bulging of a semiconductor package, a reduction in a number of faulty or missed electrical connections between various semiconductor components and the substrate, and similar benefits) may be similarly realized by mounting another semiconductor die to the substrate using a non-conductive film and/or without the use of an epoxy underfill.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIGS. 3A-3B are provided as an example. Other examples may differ from what is described with regard to FIG. 3A-3B.

FIG. 4 is a diagram of example equipment 400 used to manufacture various semiconductor die described herein. As shown in FIG. 4, equipment 400 may include a die attachment system 402, such as for attaching a flip chip die to a substrate. The die attachment system 402 may include one or more devices or tooling, such as a printing machine 404, a film laminator 406, a wafer dicing machine 408, a boat carrier 410, a die placement tool 412, a reflow oven 414, a flux cleaner 416, a plasma chamber 418, an underfill dispenser 420, and/or a cure device 422. One or more devices may be may physically or communicatively coupled to one another. For example, one or more devices may interconnect via wired connections and/or wireless connections, such as via a bus 424. Additionally, or alternatively, one or more devices may form part of an electronics assembly manufacturing line.

The printing machine 404 may be a device capable of printing patterns in silicon, forming an integrated circuit of a flip chip die. In some implementations, the printing machine 404 may be a lithography device capable of printing patterns in silicon to form an integrated circuit. Additionally, or alternatively, the printing machine may be capable of applying solder or other electrically conductive material to a flip chip die to form a portion of an electrical connection to be formed between a semiconductor die and a substrate. For example, the printing machine 404 may be capable of applying a grid of solder bumps to a flip chip die, which will align with a grid of bump pads on a substrate during a flip chip attachment process.

The film laminator 406 may be a device capable of laminating a film, such as the non-conductive film 226 and/or the non-conductive film 334, onto a flip chip die. In some implementations, the film laminator 406 may be a device capable of applying a non-conductive film to a wafer (e.g., the film laminator 406 may be configured to apply a non-conductive film to multiple flip chip die or other semiconductor die prior to the die being diced from the wafer), while, in some other implementations, the film laminator 406 may be a device capable of applying a non-conductive film to an individual flip chip die (e.g., a die after it has been diced from a wafer). In some implementations, the film laminator may be capable of dispensing, placing, and cutting a non-conductive film, and thus may include one or more film dispensers, one or more cutter blades and/or lasers for cutting the non-conductive film, or the like.

The wafer dicing machine 408 may be a device capable of dicing a flip chip die, such as the controller 206 and/or the controller 306, from a wafer. In some implementations, the wafer dicing machine 408 may be capable of dicing one or more flip chip die from a wafer following a lamination step, in which a non-conductive film is laminated onto the wafer, as is described in more detail below. In some implementations, the wafer dicing machine 408 may include one or more blades and/or one or more lasers to dice the flip chip die from the wafer.

The boat carrier 410 may be device capable of supporting and/or carrying a substrate during a flip chip attachment process. The boat carrier 410 may be constructed from a non-contaminating material, such as quartz, and may be capable of withstanding high temperatures. In that regard, the boat carrier 410 may be capable of carrying a substrate and/or a flip chip die through one or more ovens, such as a reflow oven 414 and/or a cure device 422.

The die placement tool 412 may be a high-precision tool capable of placing a flip chip die onto a substrate. In some implementations, the die placement tool 412 may be capable of flipping a flip chip die during a placement process, such that an active surface, which may be facing up during a non-conductive film lamination step or the like, may face the substrate during the flip chip die placement process. In some implementations, the die placement tool 412 may include one or more sensors capable of aligning bump bonds on the flip chip die with bond pads on a substrate during a flip chip die attachment process.

The reflow oven 414 may be capable of heating a substrate and flip chip die to a suitable temperature to cause a reflow of solder or other bonding material, thereby causing the solder or similar material to melt and make an electrical connection between two components. In some implementations, the reflow oven 414 may be capable of heating a non-conductive film laminated on a flip chip die to embed electrical connections and/or to mechanically couple a flip chip die to a substrate.

The flux cleaner 416 may be a device capable of removing residual flux from a soldering process. In some implementations, the flux cleaner 416 may include a heater capable of removing residual flux through a heat treatment process. Additionally, or alternatively, the flux cleaner 416 may include a nozzle or similar device capable of applying a cleaning agent to a flip chip die after a die attachment process in order to remove residual flux therefrom.

The plasma chamber 418 may be a device capable of providing plasma treatment to a flip chip die. In some implementations, the plasma chamber 418 may be capable of directly or indirectly applying a plasma stream to an area of a flip chip die, such as for purposes of preparing the area on the flip chip die for receiving an epoxy underfill, or the like.

The underfill dispenser 420 may be a device capable of dispensing an epoxy underfill between a flip chip die and a substrate. In some implementations, the underfill dispenser 420 may include a dispensing needle capable of applying an epoxy underfill by capillary action under pressure, such as by dispensing underfill material around a periphery of a flip chip die such that the underfill material flows beneath the die and fills a space between the die and substrate.

The cure device 422 may be a device capable of curing an underfill material, such as an epoxy underfill material. In some implementations, the cure device 422 may be an oven configured to heat an underfill material to a suitable curing temperature. Additionally, or alternatively, the cure device 422 may be capable of curing the underfill material via a chemical reaction, by the application of ultraviolet light, by the application of other radiation, or the like.

The number and arrangement of devices and networks shown in FIG. 4 are provided as an example. In practice, there may be additional devices, fewer devices, different devices, or differently arranged devices than those shown in FIG. 4. Furthermore, two or more devices shown in FIG. 4 may be implemented within a single device, or a single device shown in FIG. 4 may be implemented as multiple, distributed devices. Additionally, or alternatively, a set of devices (e.g., one or more devices) of equipment 400 may perform one or more functions described as being performed by another set of devices of equipment 400.

FIG. 5 is a diagram of an example process 500 associated with laminating a non-conductive film on a flip chip die. The example process 500 may be performed by various semiconductor equipment, such as one or more of the devices described in connection with the die attachment system 402 shown in FIG. 4.

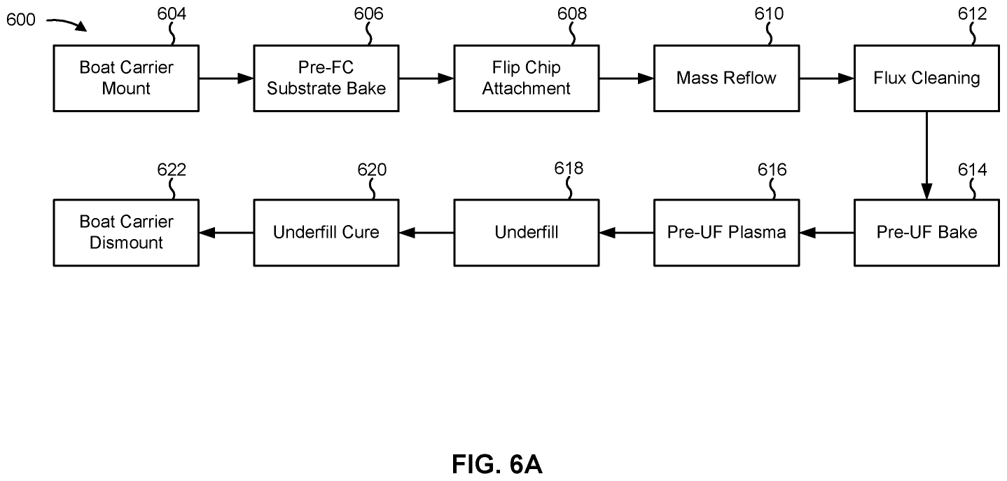

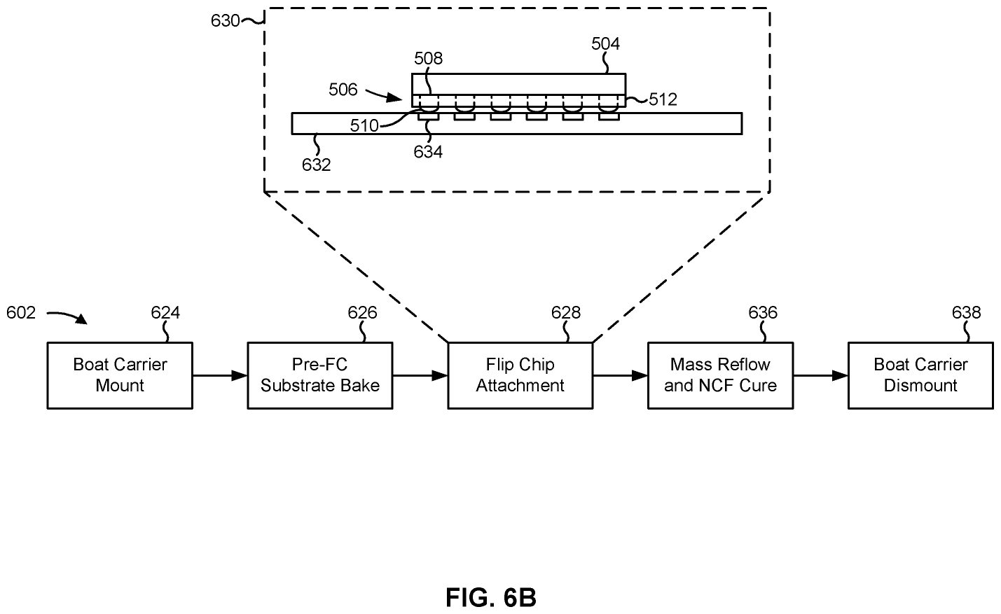

First, as shown by reference number 502, a flip chip die 504 (e.g., the controller 206, the controller 306, or a similar flip chip die) may be received by a film laminator (e.g., the film laminator 406) or a similar device. In some implementations, and as shown using dashed lines, the flip chip die 504 may be part of a wafer including multiple copies of the flip chip die 504. That is, the flip chip die 504 may be received by a film laminator as part of a wafer that has not yet been diced into individual die. In some implementations, the flip chip die 504 may include a number of electrical connections (e.g., electrical connections 224, 332, which may be formed via the printing machine 404) on a surface of the flip chip die 504, such as bumps 506 capable of bump bonding with corresponding bump pads of a substrate (which is described in more detail in connection with FIG. 6B). In some implementations, the bumps 506 may include pillar bumps 508 and/or solder bumps 510. The pillar bumps 508 may be copper pillar bumps capped with the solder bumps 510, which may include any suitable solder material for forming an electrical connection between a flip chip die and a substrate.

A non-conductive film 512 (e.g., the non-conductive film 226, the non-conductive film 334, or a similar non-conductive film) may be laminated on the flip chip die 504, such as by a film laminator (e.g., film laminator 406) or a similar device. In some implementations, the non-conductive film 512 may be formed from any suitable non-conductive material. In some implementations, the non-conductive film 512 may include one or more fillers, such as one or more nano fillers. In some implementations, a thickness of the non-conductive film 512 may correspond to a height of the pillar bumps 508 plus a thickness of the collapsed solder bumps 510. In some implementations, the thickness of the non-conductive film 512 may be between 10 micrometers (μm) and 100 μm, and more particularly between 20 μm and 60 μm. For example, in some implementations, the thickness of the non-conductive film 512 may be approximately 35 μm+/−3 μm. The non-conductive film 512 may be placed on the side of the flip chip die 504 including the bumps 506. Put another way, in some implementations, the non-conductive film 512 may be laminated over the bumps 506 of the flip chip die 504.

As shown by reference number 514, in some implementations, the non-conductive film 512 may be heated and/or cured in order to surround at least a portion of the bumps 506. For example, in some implementations, the non-conductive film 512 may be heated to near or past a melting point of the non-conductive film 512, such that the non-conductive film 512 becomes pliable and thus begins to encapsulate a portion of the bumps (such as the solder bumps 510 in the step shown by reference number 514).

As shown by reference number 516, in some implementations, the non-conductive film 512 may be heated and/or cured (e.g., via the reflow oven 414 and/or the cure device 422) until the non-conductive film 512 surrounds the pillar bumps 508 and/or exposes the solder bumps 510. Put another way, the non-conductive film 512 may be laminated over the bumps 506, and subjected to a cure step in which the non-conductive film 512 melts and fuses around the pillar bumps 508, exposing the solder bumps 510, such that, after the cure step, a surface of the flip chip die 504 may include a plurality of pillar bumps 508 surrounded by the non-conductive film 512 with an exposed solder bump 510 on a distal end of each pillar bump 508. Moreover, in implementations in which the non-conductive film 512 is laminated over a wafer containing multiple copies of the flip chip die 504, the flip chip die 504 may then be singulated (e.g., via the wafer dicing machine 408), such as by dicing the flip chip die 504 (and thus the non-conductive film 512 provided thereon) from the wafer.

As indicated above, FIG. 5 is provided as an example. Other examples may differ from what is described with regard to FIG. 5.

FIG. 6A is a diagram of an example process flow 600 associated with attaching a flip chip die to a substrate using an underfill process, and FIG. 6B is an example process flow 602 associated with attaching a flip chip die to a substrate using a non-conductive film. As seen by comparing the steps of process flow 600 with the steps of process flow 602, in some implementations, replacing the use of an epoxy underfill with the use of a non-conductive film may reduce a manufacturing cycle time associated with creating a semiconductor package and thus increase manufacturing throughput associated with creating a semiconductor package. For example, in some implementations, a number of steps associated with mounting a flip chip die to a substrate may be reduced by approximately 50%.

First, a process flow 600 that includes mounting a flip chip die to a substrate using an epoxy underfill (such as mounting the controller 206 to the substrate 204 and/or mounting the controller 306 to the substrate 304), may first include mounting a substrate to a carrier, sometimes referred to as a boat carrier (e.g., the boat carrier 410), as shown by reference number 604. As described above in connection with FIG. 4, the boat carrier may be an apparatus configured to carry a wafer, a substrate, a semiconductor device, or a similar component through various manufacturing steps and/or stations, such as the manufacturing steps described herein. The boat carrier may be manufactured from quartz or a similar non-contaminating material.

As shown by reference number 606, the substrate may be subjected to a pre-flip chip (pre-FC) substrate bake. For example, the boat carrier including the substrate may be placed in a furnace or similar apparatus (e.g., the reflow oven 414, the cure device 422, or a similar device) configured to heat the substrate and/or otherwise prepare the substrate for mounting one or more semiconductor components thereto.

As shown by reference number 608, a flip chip die may be attached to the substrate. As described above, a flip chip die may be formed with a plurality of conductive external contacts, typically in the form of solder balls or bumps, arranged in a grid pattern on an active surface of the flip chip die. To attach such a die to the substrate, the die is flipped over and placed on the substrate. In the step shown by reference number 608, the solder balls or bumps of the flip chip die may be aligned with bump pads on the substrate (which is described in more detail below in connection with reference number 628). Then, as shown by reference number 610, the solder balls or bumps may be subjected to a mass reflow process, such as by placing the substrate and flip chip die is a reflow oven 414, or the like. During a mass reflow process, the solder balls or bumps may be heated to a melting point such that the solder bumps or balls melt and fuse with electrical connections and/or terminals provided on the substrate and aligned with the solder balls or bumps.

As shown by reference number 612, the substrate with the flip chip die attached thereto may undergo a flux cleaning process, such as via flux cleaner 416. This may include removing flux residues underneath the flip die that remain after the mass reflow process. Removing flux residues may help prevent delamination of underfill from the flip chip die and/or substrate during an operation life of a semiconductor assembly. Following the flux cleaning process, the substrate with the flip chip die attached thereto may undergo one or more pre-underfill (pre-UF) processing steps. For example, as shown by reference number 614, the substrate and flip chip die may undergo a pre-UF bake process, which may include heating the substrate and the flip chip in preparation of applying an underfill (such as via the reflow oven 414, the cure device 422, or a similar device). Additionally, or alternatively, as shown by reference number 616, the substrate and flip chip die may undergo a pre-UF plasma step, which may include treating the substrate and flip chip die with plasma (such as via a plasma chamber 418), which may reduce voids in underfill, improve adhesion of the underfill, increase wicking speeds associated with the underfill, among other benefits.

As shown by reference number 618, an underfill may be applied between flip chip die and the substrate, such as a via an underfill dispenser 420 (e.g., a dispensing needle, as described). More particularly, a dielectric (e.g., epoxy) underfill (e.g., epoxy underfill 214, epoxy underfill 318, or a similar underfill material) may be injected between the flip chip die and the surface of the substance to embed the electrical connections and to mechanically couple the flip chip die to the substrate. As described above, the epoxy underfill may control stress that may otherwise be placed on the electrical connections due to thermal expansion or the like. As shown by reference number 620, the substrate, flip chip die, and epoxy underfill may then undergo an underfill cure process, such as via cure device 422. For example, for a thermoset epoxy polymer, the underfill cure process may include heating the epoxy underfill to a suitable temperature causing the epoxy underfill to harden and/or cure. For a thermoplastic epoxy polymer, the underfill cure process may include cooling the epoxy underfill to a suitable temperature causing the epoxy underfill to harden and/or cure. Finally, as shown by reference number 622, the substrate and flip chip die (including the cured epoxy underfill therebetween) may be removed, or dismounted, from the boat carrier.

In contrast, and a shown in FIG. 6B, when a flip chip die is mounted to a substrate using a non-conductive film (such as the controller 206, 306 in the implementations described in connection with apparatuses 202 and 302), certain manufacturing steps, such as the flux cleaning step, the pre-UF bake step, the pre-UF plasma step, the underfill step, and/or the underfill cure step, may be eliminated. More particularly, in the example process flow 602, the substrate may undergo a boat carrier mount process, as shown by reference number 624, a pre-FC substrate bake process, as shown by reference number 626, and a flip chip attachment process, as shown by reference number 628, which may be substantially similar to the boat carrier mount process described in connection with reference number 604, the pre-FC substrate bake process described in connection with reference number 606, and the flip chip attachment process described in connection with reference number 608, respectively.

In this implementation, however, the flip chip die may include a non-conductive film laminated onto the flip chip die prior to placing the flip chip die on the substrate. More particularly, as shown by reference number 630, during the flip chip attachment step, the flip chip die 504 with the non-conductive film 512 laminated thereon (described above in connection with FIG. 5) may be flipped over and placed on a substrate 632, such as via the die placement tool 412. In this way, the plurality of bumps 506 on the flip chip die 504 surface may be aligned with a plurality of corresponding bump pads 634 provided on a surface of the substrate 632. As described above in connection with FIG. 5, in some implementations, during lamination of the non-conductive film 512 on the flip chip die 504, the non-conductive film 512 may be cured to expose the plurality of solder bumps 510 on the distal ends of the plurality of pillar bumps 508. Accordingly, when the flip chip die 504 is placed on the substrate 632, each solder bump 510 may contact a corresponding bump pad 634, as shown.

As shown by reference number 636, the substrate 632 with the flip chip die 504 placed thereon may then undergo a mass reflow process and/or a non-conductive film (indicated as “NCF’ in FIG. 6B) cure process, such as via the reflow oven 414 and/or the cure device 422, in order to provide an electrical connection between the flip chip die 504 and the substrate 632. In this regard, the mass reflow process may be substantially similar to the mass reflow process described above in connection with reference number 610. In this implementation, however, in addition to heating the solder bumps 510 and thus establishing an electrical connection between the flip chip die 504 and the substrate 632, during the mass reflow process the non-conductive film 512 may be heated and cured between the flip chip die 504 and the substrate 632, thus mechanically coupling the flip chip die 504 to the substrate 632. In some implementations, the non-conductive film 512 may embed the electrical connections between the flip chip die 504 and the substrate 632, thereby isolating and/or protecting the electrical connections, as well as serve to control stress that may otherwise be placed on the electrical connections due to thermal expansion or the like.

Notably, because the non-conductive film 512 is provided with the flip chip die 504 and/or heated and cured in place during the mass reflow step, the additional processing steps associated with an underfill process (e.g., the flux cleaning process described in connection with reference number 612, the pre-UF bake process described in connection with reference number 614, the pre-UF plasma process described in connection with reference number 616, the underfill application process described in connection with reference number 618, and/or the underfill cure process described in connection with reference number 620) may be eliminated. Accordingly, following the mass reflow process, the substrate 632 with the flip chip die 504 attached thereto, and with the non-conductive film 512 disposed between the substrate 632 and the flip chip die 504, may undergo a boat carrier dismount process, as shown by reference number 638, which may be substantially similar to the boat carrier dismount process described above in connection with reference number 622. Thus, by attaching a flip chip die to a substrate using a non-conductive film and thus omitting the use of an epoxy underfill, certain steps associated with a flip chip die attachment process may be eliminated, thereby reducing manufacturing time and increasing manufacturing throughout.

As indicated above, FIG. 6 is provided as an example. Other examples may differ from what is described with regard to FIG. 6.

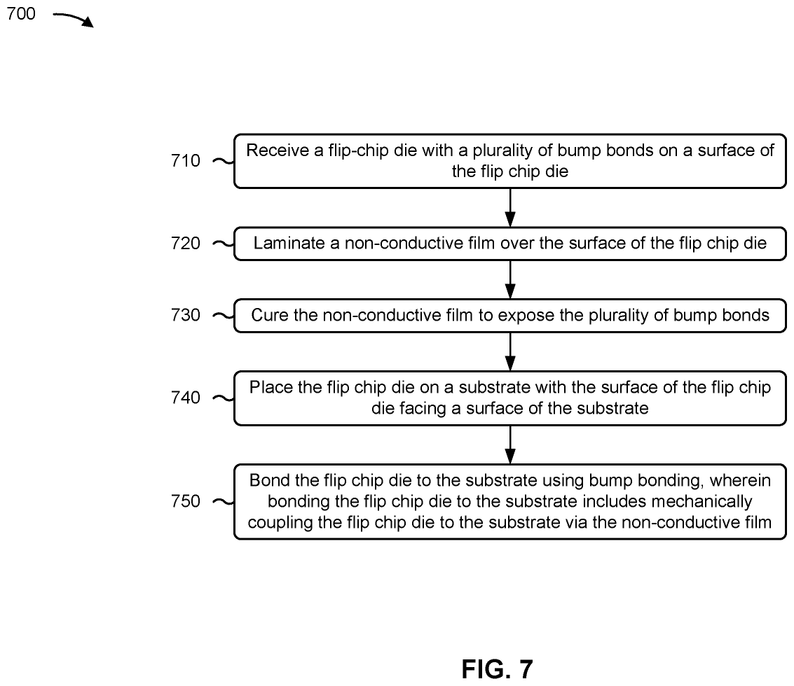

FIG. 7 is a flowchart of an example method 700 of forming an integrated assembly or memory device having a non-conductive film for bonding a flip chip die to a substrate. In some implementations, one or more process blocks of FIG. 7 may be performed by various semiconductor manufacturing equipment, such as the equipment and/or tooling described in connection with FIG. 4 or similar devices.

As shown in FIG. 7, the method 700 may include receiving a flip chip die with a plurality of bump bonds on a surface of the flip chip die (block 710). As further shown in FIG. 7, the method 700 may include laminating a non-conductive film over the surface of the flip chip die (block 720). As further shown in FIG. 7, the method 700 may include curing the non-conductive film to expose the plurality of bump bonds (block 730). As further shown in FIG. 7, the method 700 may include placing the flip chip die on a substrate with the surface of the flip chip die facing a surface of the substrate (block 740). As further shown in FIG. 7, the method 700 may include bonding the flip chip die to the substrate using bump bonding, wherein bonding the flip chip die to the substrate includes mechanically coupling the flip chip die to the substrate via the non-conductive film (block 750).

The method 700 may include additional implementations, such as any single implementation or any combination of implementations described below and/or in connection with one or more other methods described elsewhere herein.

In some implementations, mechanically coupling the flip chip die to the substrate via the non-conductive film includes curing the non-conductive film between the flip chip die and the substrate. In some implementations, mechanically coupling the flip chip die to the substrate via the non-conductive film includes mechanically coupling the flip chip die to the substrate without the use of an epoxy underfill. In some implementations, the method 700 includes bonding a plurality of memory chips to the substrate.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the apparatus 202 and/or the apparatus 302, an integrated assembly that includes the apparatus 202 and/or the apparatus 302, any part described herein of the apparatus 202 and/or the apparatus 302, and/or any part described herein of an integrated assembly that includes the apparatus 202 and/or the apparatus 302. For example, the method 700 may include forming one or more of the parts 206, 208, 210, 218, 224, 226, 306, 308, 310, 312, 314, 324, 332, and/or 334.

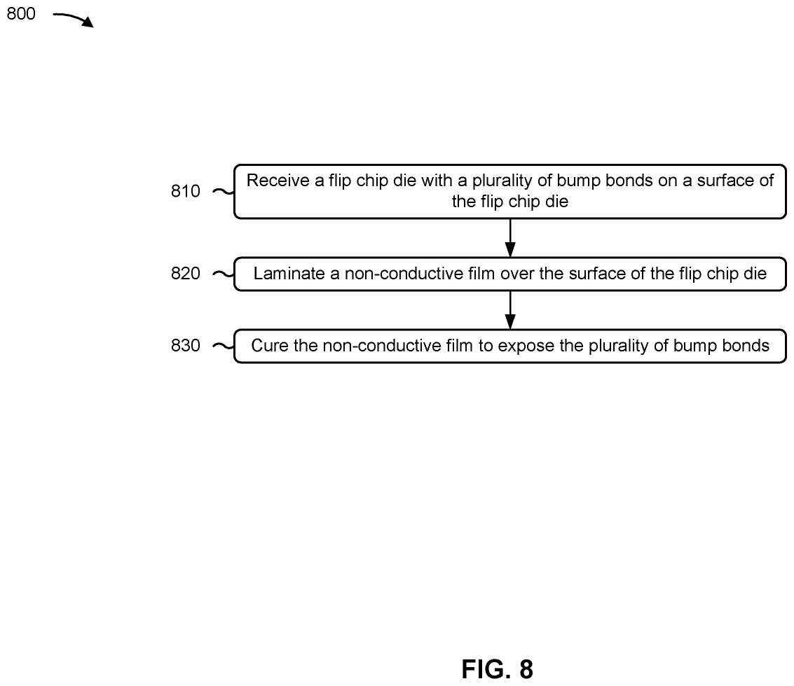

FIG. 8 is a flowchart of an example method 800 of forming a flip chip die having a non-conductive film for bonding the flip chip die to a substrate. In some implementations, one or more process blocks of FIG. 8 may be performed by various semiconductor manufacturing equipment.

As shown in FIG. 8, the method 800 may include receiving a flip chip die with a plurality of bump bonds on a surface of the flip chip die (block 810). As further shown in FIG. 8, the method 800 may include laminating a non-conductive film over the surface of the flip chip die (block 820). As further shown in FIG. 8, the method 800 may include curing the non-conductive film to expose the plurality of bump bonds (block 830).

The method 800 may include additional implementations, such as any single implementation or any combination of implementations described below and/or in connection with one or more other methods described elsewhere herein.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the apparatus 202 and/or the apparatus 302, an integrated assembly that includes the apparatus 202 and/or the apparatus 302, any part described herein of the apparatus 202 and/or the apparatus 302, and/or any part described herein of an integrated assembly that includes the apparatus 202 and/or the apparatus 302. For example, the method 800 may include forming one or more of the parts 206, 208, 210, 218, 224, 226, 306, 308, 310, 312, 314, 324, 332, and/or 334.

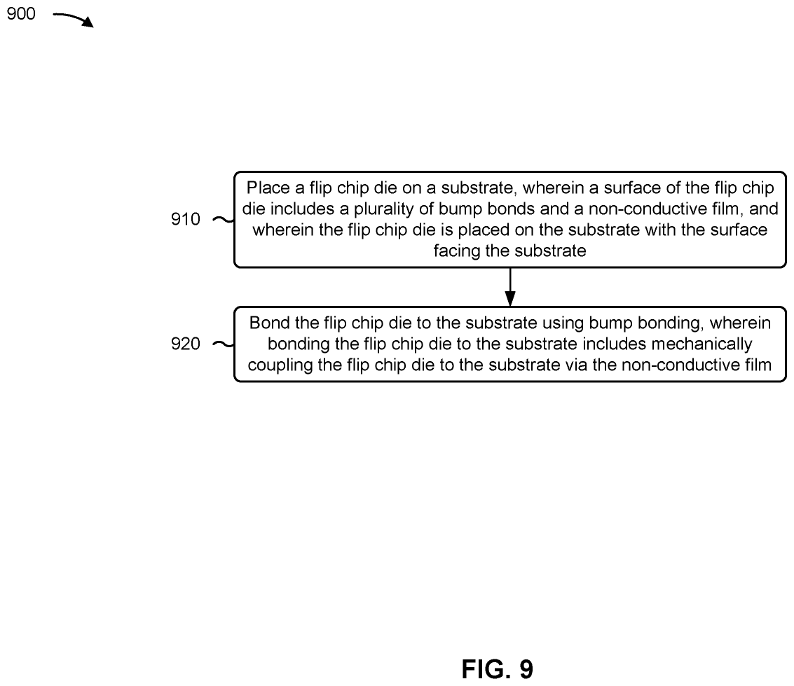

FIG. 9 is a flowchart of an example method 900 of forming an integrated assembly or memory device having a non-conductive film for bonding a flip chip die to a substrate. In some implementations, one or more process blocks of FIG. 9 may be performed by various semiconductor manufacturing equipment.

As shown in FIG. 9, the method 900 may include placing a flip chip die on a substrate, wherein a surface of the flip chip die includes a plurality of bump bonds and a non-conductive film, and wherein the flip chip die is placed on the substrate with the surface facing the substrate (block 910). As further shown in FIG. 9, the method 900 may include bonding the flip chip die to the substrate using bump bonding, wherein bonding the flip chip die to the substrate includes mechanically coupling the flip chip die to the substrate via the non-conductive film (block 920).

The method 900 may include additional implementations, such as any single implementation or any combination of implementations described below and/or in connection with one or more other methods described elsewhere herein.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming the apparatus 202 and/or the apparatus 302, an integrated assembly that includes the apparatus 202 and/or the apparatus 302, any part described herein of the apparatus 202 and/or the apparatus 302, and/or any part described herein of an integrated assembly that includes the apparatus 202 and/or the apparatus 302. For example, the method 900 may include forming one or more of the parts 206, 208, 210, 218, 224, 226, 306, 308, 310, 312, 314, 324, 332, and/or 334.

In some implementations, a semiconductor device assembly includes a substrate; a flip chip die electrically coupled to the substrate via a plurality of electrical connections; and a non-conductive film disposed between the flip chip die and the substrate, wherein the non-conductive film surrounds the plurality of electrical connections and mechanically couples the flip chip die to the substrate.

In some implementations, a memory device includes a substrate; a plurality of memory chips coupled to the substrate; a flip chip controller electrically coupled to the substrate via a plurality of bump bonds and configured to control one or more operations of the plurality of memory chips; and a laminated, non-conductive film on the flip chip controller and sandwiched between the flip chip controller and the substrate, wherein the non-conductive film surrounds the plurality of bump bonds and mechanically couples the flip chip controller to the substrate.

In some implementations, a method includes receiving a flip chip die with a plurality of bump bonds on a surface of the flip chip die; laminating a non-conductive film over the surface of the flip chip die; curing the non-conductive film to expose the plurality of bump bonds; placing the flip chip die on a substrate with the surface of the flip chip die facing a surface of the substrate; and bonding the flip chip die to the substrate using bump bonding, wherein bonding the flip chip die to the substrate includes mechanically coupling the flip chip die to the substrate via the non-conductive film.

In some implementations, a method includes receiving a flip chip die with a plurality of bump bonds on a surface of the flip chip die; laminating a non-conductive film over the surface of the flip chip die; and curing the non-conductive film to expose the plurality of bump bonds.

In some implementations, a method includes placing a flip chip die on a substrate, wherein a surface of the flip chip die includes a plurality of bump bonds and a non-conductive film, and wherein the flip chip die is placed on the substrate with the surface facing the substrate; and bonding the flip chip die to the substrate using bump bonding, wherein bonding the flip chip die to the substrate includes mechanically coupling the flip chip die to the substrate via the non-conductive film.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a flip chip die electrically coupled to the substrate via a plurality of electrical connections; and
a non-conductive film disposed between the flip chip die and the substrate, wherein the non-conductive film surrounds the plurality of electrical connections and mechanically couples the flip chip die to the substrate.

2. The semiconductor device assembly of claim 1, further comprising at least one semiconductor die electrically coupled to the substrate, wherein the flip chip die is a flip chip controller configured to control one or more operations of the at least one semiconductor die.

3. The semiconductor device assembly of claim 2, wherein the flip chip controller is disposed less than 700 micrometers from a closest edge of the at least one semiconductor die.

4. The semiconductor device assembly of claim 2, wherein the flip chip controller is disposed approximately 50 micrometers from a closest edge of the at least one semiconductor die.

5. The semiconductor device assembly of claim 1, wherein the flip chip die includes a plurality of pillar bumps and a plurality of solder bumps, wherein the non-conductive film surrounds the plurality of pillar bumps and exposes the plurality of solder bumps.

6. The semiconductor device assembly of claim 1, wherein the non-conductive film is laminated on a surface of the flip chip die that faces the substrate.

7. The semiconductor device assembly of claim 1, wherein a periphery of the non-conductive film does not extend beyond a periphery of the flip chip die.

8. The semiconductor device assembly of claim 1, wherein the flip chip die is mechanically coupled to the substrate without use of an epoxy underfilling.

9. The semiconductor device assembly of claim 1, further comprising a bond finger on the substrate, wherein the flip chip die is disposed less than 1000 micrometers from a closest edge of the bond finger.

10. The semiconductor device assembly of claim 1, further comprising a bond finger on the substrate, wherein the flip chip die is disposed approximately 50 micrometers from a closest edge of the bond finger.

11. The semiconductor device assembly of claim 1, wherein a periphery of the semiconductor device assembly is less than 13 millimeters by 11.5 millimeters.

12. The semiconductor device assembly of claim 1, wherein a periphery of the semiconductor device assembly is approximately 13 millimeters by approximately 9.5 millimeters.

13. A memory device, comprising:
a substrate;
a plurality of memory chips coupled to the substrate;
a flip chip controller electrically coupled to the substrate via a plurality of bump bonds and configured to control one or more operations of the plurality of memory chips; and
a laminated, non-conductive film on the flip chip controller and sandwiched between the flip chip controller and the substrate, wherein the non-conductive film surrounds the plurality of bump bonds and mechanically couples the flip chip controller to the substrate.

14. The memory device of claim 13, wherein the memory device is a managed NAND device.

15. The memory device of claim 13, wherein the flip chip controller includes a plurality of pillar bumps and a plurality of solder bumps, wherein the non-conductive film surrounds the plurality of pillar bumps and exposes the plurality of solder bumps.

16. The memory device of claim 13, wherein a periphery of the non-conductive film is fully contained within a periphery of the flip chip controller.

17. The memory device of claim 13, wherein the flip chip controller is mechanically coupled to the substrate without use of an epoxy underfilling.

18. The memory device of claim 13, wherein the memory device further includes a bond finger, wherein the flip chip controller is disposed less than 700 micrometers from a closest edge of the bond finger or at least one memory chip of the plurality of memory chips.

19. The memory device of claim 13, wherein the memory device further includes a bond finger, wherein the flip chip controller is disposed approximately 50 micrometers from a closest edge of the bond finger or at least one memory chip of the plurality of memory chips.

20. The memory device of claim 13, wherein a periphery of the memory device is smaller than 13 millimeters by 11.5 millimeters.

21. The memory device of claim 13, wherein a periphery of the memory device is approximately 13 millimeters by approximately 9.5 millimeters.

22. A method, comprising:
receiving a flip chip die with a plurality of bump bonds on a surface of the flip chip die;
laminating a non-conductive film over the surface of the flip chip die;
curing the non-conductive film to expose the plurality of bump bonds;
placing the flip chip die on a substrate with the surface of the flip chip die facing a surface of the substrate; and
bonding the flip chip die to the substrate using bump bonding, wherein bonding the flip chip die to the substrate includes mechanically coupling the flip chip die to the substrate via the non-conductive film.

23. The method of claim 22, wherein mechanically coupling the flip chip die to the substrate via the non-conductive film includes curing the non-conductive film between the flip chip die and the substrate.

24. The method of claim 22, wherein mechanically coupling the flip chip die to the substrate via the non-conductive film includes mechanically coupling the flip chip die to the substrate without use of an epoxy underfill.

25. The method of claim 22, further comprising bonding a plurality of memory chips to the substrate.
